(19) United States
(12) Patent Application Publication
(10) Pub. No.: US 2005/0233563 A1
(43) Pub. Date: Oct. 20, 2005

(54) Recess reduction for leakage improvement in high density capacitors

(75) Inventors: Lindsey H. Hall, Plano, TX (US); Satyavolu Srinivas Papa Rao, Garland, TX (US); Gad Simcha Haase, Plano, TX (US); Asad M. Haider, Plano, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 10/825,351

(22) Filed: Apr. 15, 2004

(51) Int. Cl. H01L 21/331; H01L 21/8222; H01L 21/44

(52) U.S. Cl. 438/597

(57) ABSTRACT

The present invention provides a capacitor [205]. The capacitor [205] includes a first conductive layer [206] located on an interconnect structure [226] formed in a dielectric layer [228], a capacitor dielectric layer [208] located over the first conductive layer [206] and a second conductive layer [210] located over the capacitor dielectric layer [208]. The recess relief in the surface of the dielectric layer [228] attributable to a fabrication process has been reduced about the interconnect structure [226] to provide a more planar deposition surface over which the capacitor's [205] layers may be deposited.

### TECHNICAL FIELD OF THE INVENTION

The present invention is directed, in general, to a method for manufacturing a semiconductor device, and, more specifically, to a method for reducing recesses around interconnect structures to improve capacitor leakage.

### BACKGROUND OF THE INVENTION

High performance integrated circuits have gained wide acceptance and utility in present day technologies, and the use of capacitors in these integrated circuits is almost universal. In addition, however, there is a great demand for shrinking these semiconductor devices to provide increased device density on the semiconductor chip and provide chips that are faster, but at the same time, are energy efficient.

A typical integrated circuit will often include metal-insulator-metal (MIM) capacitors, which are most often formed over an existing contact plug or via. These MIM capacitors have gained wide acceptance because they can be easily integrated into existing process flows. In a conventional fabrication process, contact openings or vias are first formed in a dielectric layer. These openings are then filled with a conductive metal, such as tungsten or copper. The deposition process leaves excess conductive metal on the surface of the dielectric layer that is removed by conventional chemical/mechanical polishing (CMP) processes. The CMP process produces a substantially planar surface at this point. However, the CMP process also leaves metal residue on the dielectric surface that must be cleaned to avoid defects and shorts from occurring within the integrated circuit device.

To remove this post planarization metallic residue, a post-planarization clean process is conducted. Since the solution used in the clean is intended to remove metal residue, it also removes a portion of the metal within the contact plug or via opening and results in a recess, as illustrated in FIG. 1A.

FIG. 1A is a sectional view taken with a transmission electron microscope (TEM) of a device fabricated in accordance with conventional processes, and it shows interconnect structures 110 subsequent to a post-planarization clean step. As seen in FIG. 1A, the interconnect structures 110 that are formed in a dielectric layer 115 each have a recessed area 120 that is the result of the post-planarization clean step. While the depth of these recesses may vary from the center of a wafer to its edge, the depth typically ranges from about 15 nm to about 20 nm. Given the relative size of the device, this recess depth produces a sharp edged feature over which the capacitors layers are deposited.

With reference now to FIG. 1B, there is shown a sectional view taken with a TEM of a partially formed capacitor fabricated in accordance with conventional processes. Following the post-planarization clean step, a first or bottom metal layer 125 is blanket deposited over the surface of the dielectric layer 115 and over at least one of the interconnect structures 110. As shown, the first metal layer 125 is also deposited in the recessed area 120 over the sharp interface. Following the deposition of the first metal layer 125, a capacitor dielectric layer 130 is blanket deposited over first metal layer 125, after which a second or top metal layer 135 is deposited over the capacitor dielectric layer 130.

At larger device dimensions, MIM capacitor structures, such as those illustrated in FIG. 1B worked well with either an acceptable amount of or no leakage. However, as overall device sizes have continued to shrink and the number of contacts have increased, it has been found that the leakage associated with these conventional capacitor structures is proportional to the number of contacts under the MIM capacitor structures, and thus, the leakage has increased to levels that are undesirable given present day performance requirements.

Accordingly, what is needed in the art is a capacitor that does not suffer from the disadvantages associated with conventional capacitors, as discussed above.

### SUMMARY OF THE INVENTION

To address the above-discussed deficiencies of the prior art, the present invention provides a method for reducing recess relief within an interconnect structure located in a semiconductor layer. In one advantageous embodiment, the method includes conducting a fabrication process on an interconnect structure that recesses the interconnect structure and forms a recessed substrate, and conducting a recess reduction etch to remove a portion of the recessed substrate to reduce a relief of the recessed substrate.

In another embodiment, the present invention provides a capacitor. In this embodiment, the capacitor includes a first conductive layer located on an interconnect structure formed in a dielectric layer, wherein a surface of the dielectric layer is substantially planar about the interconnect structure. The capacitor further includes a capacitor dielectric layer located over the first conductive layer and a second conductive layer located over the capacitor dielectric layer.

In another aspect, the present invention provides a method of fabricating an integrated circuit. This embodiment includes forming transistors on a semiconductor substrate, depositing dielectric layers over the transistors, forming interconnect structures in the dielectric layers, and forming a MIM capacitor on at least one of the interconnect structures. The step of forming the MIM capacitor includes conducting a fabrication process on an interconnect structure that recesses the interconnect structure and forms a recessed dielectric layer, and conducting a recess reduction etch on the recessed dielectric layer. The recess reduction etch reduces the recessed substrate to form a substantially planar surface about the interconnect structure, prior to forming the metal-insulator-metal capacitor.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention.

### BRIEF DESCRIPTION OF THE DRAWINGS

For a more complete understanding of the present invention, reference is now made to the following detailed description taken in conjunction with the accompanying FIGUREs. It is emphasized that various features may not be drawn to scale. In fact, the dimensions of various features may be arbitrarily increased or reduced for clarity of discussion. In addition, it is emphasized that some circuit components may not be illustrated for clarity of discussion. Reference is now made to the following descriptions taken in conjunction with the accompanying drawings, in which:

FIG. 1A illustrates a sectional view of an image taken with a TEM of conventional dielectric substrate subsequent to a post-planarization clean process and the recesses formed by that clean process.

FIG. 1B illustrates a sectional view of an image taken with a TEM of a conventional MIM capacitor formed over the recessed dielectric substrate;

FIG. 2 illustrates a sectional view of a partially integrated circuit that includes a capacitor;

FIG. 3A illustrates a partial sectional view of the integrated circuit of FIG. 2 at an early stage of manufacture;

FIG. 3B illustrates the device of FIG. 3A subsequent to a conventional CMP process, but prior to a post-planarization clean step;

FIG. 3C illustrates the device of FIG. 3B subsequent to the post-planarization clean step;

FIG. 3D illustrates a sectional view of the device of FIG. 3C undergoing a recess reduction etch following the post-planarization clean step; and

FIG. 3E illustrates a TEM sectional view of an embodiment of an actual interconnect structure subsequent to the recess reduction etch process as provided herein.

### DETAILED DESCRIPTION

The present invention uniquely recognizes that conventional capacitors, such as MIM capacitors, suffer from leakage primarily because of the sharp, non-planar topography over which the capacitor is built. Moreover, it has been found that this sharp relief also causes leakage to increase as capacitor density increases. As discussed above, during fabrication of interconnect structures, such as contact plugs, fabrication processes, such as planarization processes or post-planarization clean steps or other processes, are conducted to planarize the dielectric layer or remove CMP residues from the surface of the dielectric. Planarization steps can sometimes remove enough of the contact plug or via material to yield a recessed substrate. Additionally, inasmuch as the clean chemistry is designed to remove metal residues, it also attacks the metal within the interconnect structure, which also results in sharp topographical relief within the interconnect structure itself. The sharp relief caused by these fabrication processes can be significant. For example, the post-planarization clean step can result in recesses having a depth relief that can range from about 15 nm to about 20 nm.

As device sizes have decreased, there has also been a corresponding decrease in the thickness of the layers used to form capacitors. At larger device levels, the relief within the interconnect structure that stemmed from the post-planarization clean step did not present a significant problem. However, as layer thicknesses have decreased to accommodate the overall decrease in device size, it has been presently recognized that the capacitors have an unacceptable amount of leakage associated with them. Morever, it has been noted that this leakage has almost a linear relationship with underlying contact or via density. That is, contact or via device density has increased, overall leakage in the capacitors has also increased.

To remedy this problem, the present invention uniquely recognizes the need to conduct a recess reduction etch subsequent to a conventional post-planarization clean. The recess reduction etch is designed to selectively etch the dielectric layer, and thereby, reduce the amount of relief formed during the clean step and preferably without significant oxidation to the conductive material within the interconnect structure. Preferably, the height of the dielectric layer, at least about the interconnect structure, is substantially reduced. Of course, in certain applications, the recess reduction etch may globally planarize the dielectric layer as well. In fact, less than a 12% center-to-edge non-uniformity has been achieved using the process provided by the present invention. The relief reduction achieved reduces the amount of leakage associated with the capacitor, because the recess reduction about the interconnect structure allows for a more even and uniform deposition of the capacitor's layers. This, in turn, provides a capacitor that has less leakage associated with it, even when contact or via density is high.

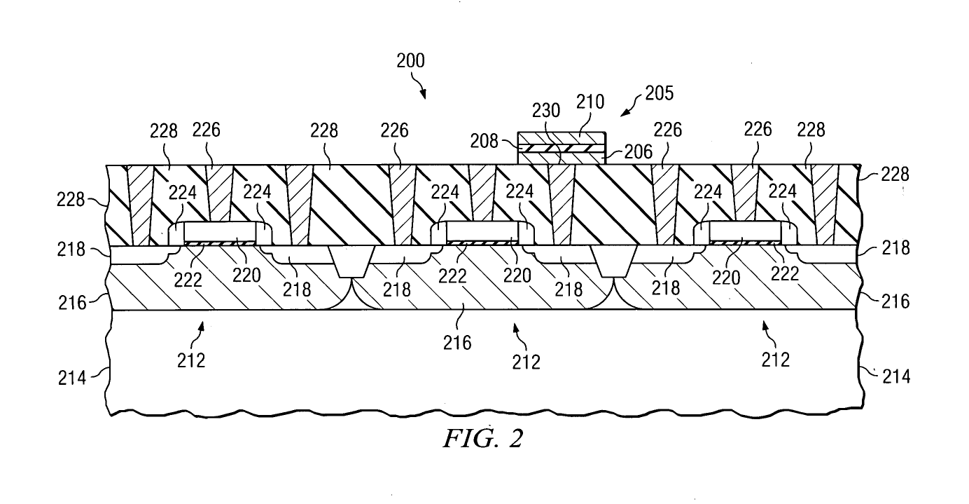

Turning initially to FIG. 2, there is illustrated a sectional view of a partially integrated circuit 200 that includes a capacitor 205. The capacitor 205 may be any many types of well known capacitors. For example the capacitor 205 may be a planar MIM capacitor or a ferro-electric random access memory (FeRAM) capacitor. The capacitor 205 includes a first conductive layer 206, or bottom electrode, a capacitor dielectric 208, and a second conductive layer 210, or top electrode. The conductive material used to form the first and second conductive layers 206,210 may be any type of conductive material known to those skilled in the art. For instance, the first conductive layer 206 may be metal or combinations of stacked metals or a conductively doped semiconductor material. The capacitor dielectric 208 may also be made of conventional materials, such as a high dielectric constant material, with tantalum pentoxide being one example, or a lower dielectric constant material, such as silicon dioxide. It should be understood that the present invention is not limited by the design of the capacitor 208 or materials or combination of materials used to fabricate the capacitor 208. The thickness of each of these layers, may also vary, depending upon design. By way of an example only, the thickness of each of the first and second conductive layers 206,210 may range from about 20 nm to about 100 nm, while the thickness of the capacitor dielectric layer 208 may range from about 12 nm to about 30 nm.

As schematically illustrated, the integrated circuit 200 includes conventionally formed transistors 212 that are located over a semiconductor substrate 214. The transistors 212 include a conductive well or tub 216, in which are formed source/drains 218. Transistor gates 220 having gate dielectric layer 222 and spacers 224 formed adjacent the transistor gates 220 are located over the source/drains 218. For ease of illustration, the capacitor 205 is electrically connected to one of the transistors 212 by an interconnect structure 226 that is formed in a dielectric layer 228 located over the transistors 220. In the exemplary embodiment that is shown, the interconnect structure 226 is a contact plug that directly contacts one of the source/drains 218 of the transistor 220 with the capacitor 205.

The interconnect structure 226 is shown subsequent to a fabrication process that forms a recessed substrate and after the recess reduction etch described herein in more detail below. The recess reduction etch provides the interconnect structure 226 with a reduced recess relief surface 230 with respect to the top surface of the dielectric layer 228. As discussed herein, this recess reduction allows for a more uniform and planar deposition of one or more of the layers comprising the capacitor 205, which, in turn, leads to a decrease in the amount of leakage associated with the capacitor 205. Since one skilled in the art would understand how to complete the integrated circuit 200 to form an operative integrated circuit, those steps will not be discussed.

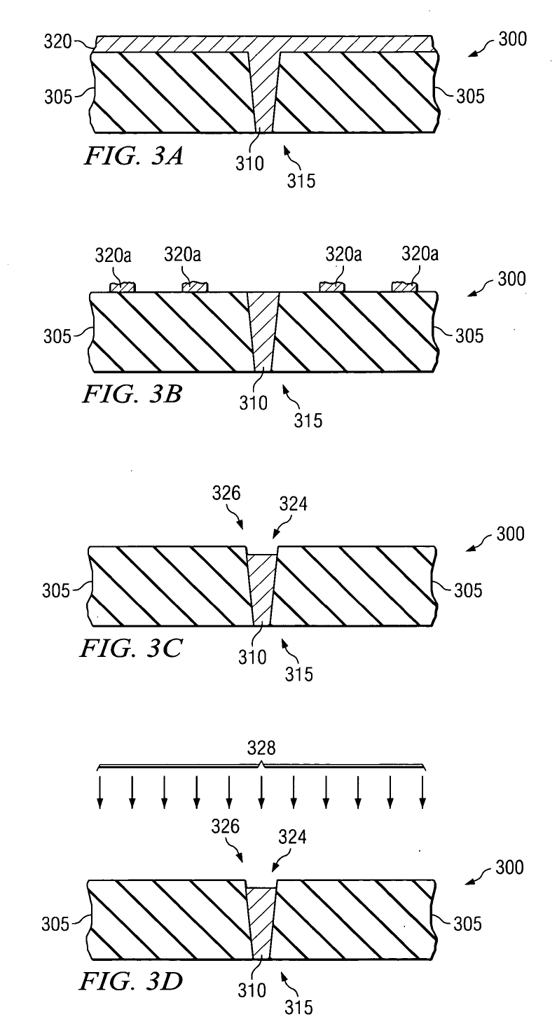

Turning now to FIG. 3A, there is shown a partial sectional view 300 of the integrated circuit 200, as generally described above, at an early stage of manufacture. In this particular view, there is illustrated a dielectric layer 305 having a conductive material 310 conventionally deposited in an opening 315 formed in the dielectric layer 305, which forms an interconnect structure. The conductive material 310, which may be, for example, tungsten or copper, is blanket deposited in such a way that it leaves a layer 320 of the conductive material 310 on the surface of the dielectric layer 305. While not shown, a barrier layer or layers, may also be conventionally deposited in the opening 315 prior to the deposition of the conductive material 310 to prevent inter diffusion between the conductive material 310 and the dielectric layer 305. One who is skilled in the art understands what barrier layers to use, depending on the conductive material 310.

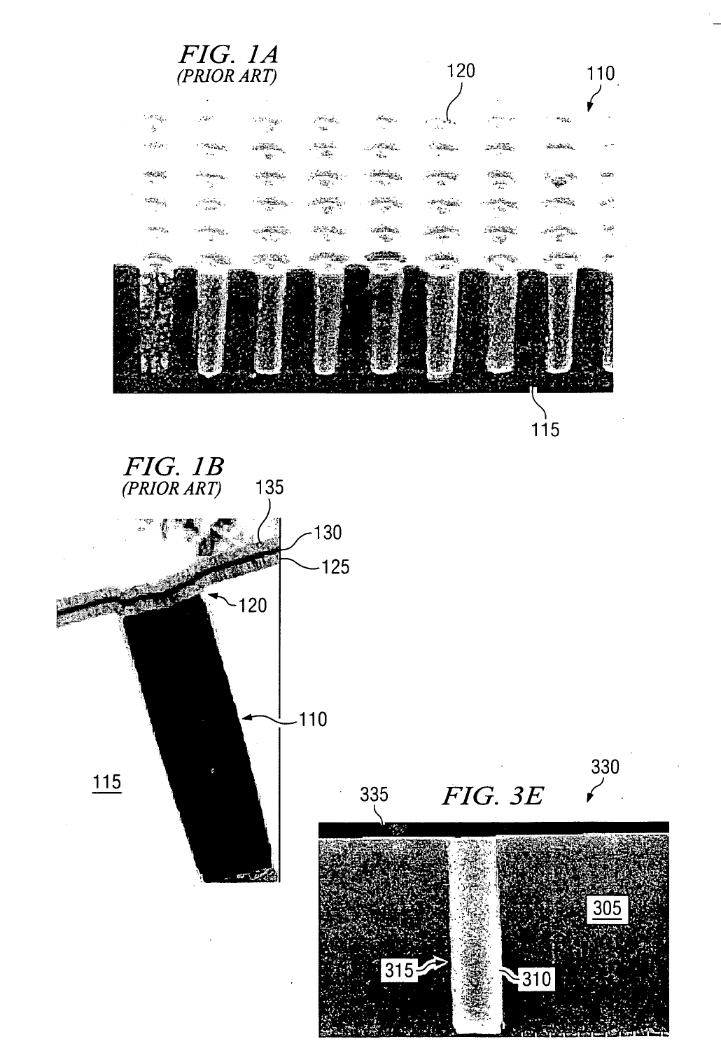

Turning now to FIGS. 3B and 3C, there is illustrated the device 300 of FIG. 3A subsequent to a conventional CMP process. As shown, the CMP process substantially planarizes the dielectric layer 305. While not shown here, it should be understood that the planarization process may also remove a portion of the conductive material 310 in the opening 315. Often, following the CMP process, the planarization process leaves a residue 320a of the conductive material layer 320 on the surface of the dielectric layer 305. To remove this residue 320a, a post-planarization clean step is often conducted. The conventional clean chemistry is selected to attack the conductive material 320 so that it will be substantially removed from the surface of the dielectric layer 305. Unfortunately, however, the clean chemistry also attacks the conductive material 310 located in the interconnect structure 315. As a result, a portion of the conductive material 310 is also removed, which forms a recess 324, as illustrated in FIG. 3C. This, in turn, produces a recessed surface 326 and as further illustrated in FIG. 1A. Depending on the process parameters and the chemistry of the clean step, the depth of the recess 324 may vary. For example, the depth of the recess 324 may range from about 15 nm to about 20 nm.

Turning now to FIG. 3D, there is illustrated a sectional view of the device 300 of FIG. 3C undergoing a recess reduction etch 328 following the post-planarization clean step. The recess reduction etch 328 is conducted to reduce the amount of relief between the top surface of the dielectric layer 305 and the top surface of the interconnect 315. Any dielectric etch scheme (i.e., gasses, flows, pressure, power, etc.) that is selective to the specific substrate dielectric layer 305, without harming the conductive material 310 located in the interconnect 315, may be used. However, in those embodiments where the conductive material 310 comprises a metal, such as tungsten, copper, or aluminum, that is susceptible to oxidization, the recess reduction etch should be conducted in a substantially non-oxidizing environment, such that little to no oxidation occurs. Thus, in such embodiments, the recess reduction etch gas should not contain oxygen.

In one embodiment, the recess reduction etch may be a plasma etch, and one example of this embodiment involves using a gas mixture that includes a compound containing fluorine. Argon and nitrogen, or hydrogen in place of or in addition to nitrogen, is also included in the gas mixture in this particular embodiment. The flow rates of the gases may vary, depending on the desired speed of the etch. However, in one particular aspect, the flow rate of fluorine containing compound is about 20 sccm, the flow rate of argon is about 100 sccm, and the flow rate of nitrogen or hydrogen is about 100 sccm. In one embodiment, the fluorine containing compound is a fluorinated hydrocarbon compound. CH₂F₂ is one such example of a fluorinated hydrocarbon compound, however, other fluorinated hydrocarbon compounds known to those skilled in the art may also be used. The recess reduction etch may be conducted at a pressure of about 50 mTorr, a power of about 500 watts, and at a chuck temperatures of about 40° C. Other exemplary etch parameters include: backside He cooling at the wafer's edge of 40 Torr and at the wafer's center of 7 Torr and an electrode gap of 27 mm. It should be noted that the process parameters discussed herein are tool specific and may vary from tool to tool. The recess reduction etch can be conducted in existing etch tools, and thus, requires no special incorporation of new equipment into the process flow.

It should be specifically understood that the above-stated parameters are exemplary in nature only and that other etch parameters are within the scope of the present invention, since etch parameters are highly dependent on the materials involved in the overall process. Further, the recess reduction etch provided by the embodiments discussed herein, the way in which they are used, and at what point they are used in the process flows are in contrast to conventional applications. Typically, etches conducted on dielectric layers are used to etch openings through those layers for the purpose of forming interconnect contact plugs or vias. As such, these etches are configured to etch through a substantial amount of dielectric material (e.g., as much as 500 nm). Unlike these conventional etches, however, the recess reduction etch provided by the present invention is used to remove a small amount of dielectric material sufficient to reduce the recess about the interconnect structure, and thereby, provide a more planar surface over which to deposit the capacitor layers. Moreover, the recess reduction etch is conducted on the dielectric layer after the formation of the interconnect structure and after a post-planarization clean step.

The time period for, and the speed at which, the recess reduction etch is conducted may also vary, depending on the amount of material that is removed. In one embodiment, where 15 nm to 20 nm of dielectric material must be removed, the recess reduction etch is conducted for about 10 seconds. If more dielectric material is to be removed to reduce the sharp relief further, the recess reduction etch could be conducted for a longer period of time or to a period of time sufficient to reduce the amount of recessed relief to the desired level.

Turning now to FIG. 3E, there is illustrated a TEM sectional view of an embodiment of an actual interconnect structure 330 subsequent to the recess reduction etch process as provided herein. As seen from the TEM of this particular embodiment, the surface 335 is substantially planar, that is, a substantial amount of the recess relief has been reduced. For example, in one embodiment, a depth of the recess that forms the recessed substrate prior to the recess reduction etch may range from about 15 nm to about 20 nm and a depth of the recess subsequent to the recess reduction etch may range from about 3 nm to about zero nm. Thus, in one embodiment, the amount of recess reduction can be as much as 15 nm to 17 nm. However, it should be noted, as discussed above, that the relief reduction around the interconnect structure 315 may vary depending on how long the device is subjected to the recess reduction etch and recess reduction etch parameters. Thus, other embodiments subsequent to the recess reduction etch may have a recess depth greater than those just mentioned above and still be within the scope of the present invention. The reduction in the recess depth provides a surface that allows for a more planar deposition of the layers comprising the capacitor. As such, leakage is reduced, thereby providing an improved capacitor that more readily meets device performance requirements. Following the recess reduction etch, conventional processes can be used to arrive at the integrated circuit device shown in FIG. 2.

Although the present invention has been described in detail, those skilled in the art should understand that they can make various changes, substitutions and alterations herein without departing from the spirit and scope of the invention in its broadest form.

1. A method of reducing recess relief within an interconnect structure located in a layer of a semiconductor device, comprising:
conducting a fabrication process on an interconnect structure located in a dielectric layer that recesses said interconnect structure and forms a recessed substrate; and
conducting a recess reduction etch to remove a portion of said recessed substrate to reduce a relief of said recessed substrate.

2. The method as recited in claim 1 wherein said recess reduction etch forms a substantially planar surface about said interconnect structure.

3. The method as recited in claim 2 wherein said method further includes forming a metal-insulator-metal capacitor over said interconnect structure, subsequent to said subjecting.

4. The method as recited in claim 1 wherein said recess reduction etch includes using a gas mixture comprising a gas compound containing fluorine, argon and nitrogen or hydrogen.

5. The method as recited in claim 1 wherein said recess reduction etch is a plasma etch and a flow rate of said gas compound containing fluorine is about 20 sccm, said argon is about 100 sccm and said nitrogen or said hydrogen is about 100 sccm.

6. The method as recited in claim 4 wherein said gas compound is a fluorinated hydrocarbon compound.

7. The method as recited in claim 6 wherein said fluorinated hydrocarbon compound is CH₂F₂.

8. The method as recited in claim 1 wherein said recess reduction etch is conducted for about 10 seconds.

9. The method as recited in claim 1 wherein said removing is conducted under substantially non-oxidizing conditions.

10. The method as recited in claim 1 wherein a depth of said recess subsequent to said recess reduction etch ranges from about 3 nm to about zero nm.

11. A capacitor, comprising
a first conductive layer located on an interconnect structure formed in a dielectric layer, wherein a surface of said dielectric layer is substantially planar about said interconnect structure located in a dielectric layer;
a capacitor dielectric layer located over said first metal layer; and
a second conductive layer located over said capacitor dielectric layer.

12. The capacitor as recited in claim 11 wherein a depth of a recess within a perimeter of said interconnect structure ranges from about 3.0 nm to about zero nm.

13. The capacitor as recited in claim 11 a thickness of said first conductive layer ranges from about 20 nm to 100 nm.

14. The capacitor as recited in claim 11 wherein said interconnect structure is a contact plug.

15. The capacitor as recited in claim 14 wherein said contact plug comprises tungsten having a barrier layer between said tungsten and said dielectric layer.

16. A method of fabricating an integrated circuit, comprising:
forming transistors on a semiconductor substrate;
depositing dielectric layers over said transistors;
forming interconnect structures in said dielectric layers; and
forming a metal-insulator-metal capacitor on at least one of said interconnect structures, including:
conducting a fabrication process on an interconnect structure that recesses said interconnect structure and forms a recessed dielectric layer; and
conducting a recess reduction on said recessed dielectric layer, said recess reduction etch reducing said recessed substrate to form a substantially planar surface about said interconnect structure, prior to forming said metal-insulator-metal capacitor.

17. The method as recited in claim 16 wherein said recess reduction etch includes using a gas mixture comprising a fluorinated hydrocarbon, argon and nitrogen or hydrogen.

18. The method as recited in claim 17 wherein said recess reduction etch is a plasma etch and a flow rate of said fluorinated hydrocarbon is about 20 sccm, said argon is about 100 sccm and said nitrogen or said hydrogen is about 100 sccm.

19. The method as recited in claim 17 wherein said recess reduction etch is conducted under substantially non-oxidizing conditions.

20. The method as recited in claim 16 wherein a depth of said recess subsequent to said recess reduction etch ranges from about 3 nm to about zero nm.
